(19) United States
(12) Patent Application Publication
(10) Pub. No.: US 2025/0004044 A1
(43) Pub. Date: Jan. 2, 2025

(54) APPARATUS AND METHOD FOR DETECTING WARPAGE IN AN ELECTRONIC SYSTEM

(71) Applicant: Intel Corporation, Santa Clara, CA (US)

(72) Inventors: Vijay HOSAMANI, Bangalore (IN); Vikas Mishra, Chandler, AZ (US); Kavitha Nagarajan, Bangalore (IN); Zaman Zaid Mulla, Mumbai (IN)

(21) Appl. No.: 18/344,869

(22) Filed: Jun. 30, 2023

(51) Int. Cl. G01R 31/28; H05K 1/02

(52) U.S. Cl. CPC G01R 31/2896; H05K 1/0268

(57) ABSTRACT

The present disclosure generally relates to an electronic system including a semiconductor package and a circuit board. The semiconductor package and the circuit board may include contact structures configurable to have an output terminal of one contact structure connected to an input terminal of another contact structure so as to render a continuous electrical pathway through the contact structures, wherein the contact structures may be configured in a daisy chain manner forming a series connection, and wherein the continuous electrical pathway may render an output pattern in response to an electrical stimulus introduced to the electronic system.

### BACKGROUND

Warpage in an electronic system including a semiconductor package may be observed over a period of the product life cycle time due to thermal stress. But there may be cases when warpage may manifest very early in the life cycle of a large semiconductor package due to mechanical stress developed by asymmetric component load distribution in the semiconductor package on a motherboard. This may result in partial contact of balls or pins during power-on, at the semiconductor package edge(s), resulting in inconsistent performance or complete functional failure. It may be difficult to attribute the root cause to this functional failure or performance degradation due to electrical deficiency of the electronic system or mechanical ball contact issue.

Indeed, it may be hard to pinpoint the problematic contact area physically, as the warpage checks may be verified for either stand-alone semiconductor package tolerance limits or for motherboard warpage manufacturing design tolerances post-assembly minus the semiconductor package. These semiconductor package contact issues may result in multiple iterations of package assembly and in delayed power-on and execution milestones.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a top view of an electronic system according to an aspect of the present disclosure;

FIG. 2 shows a warpage detection algorithm flow chart applied to the electronic system of FIG. 1; and

FIG. 3 shows a flow chart illustrating a method for forming an electronic system according to an aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

The present disclosure may attempt to address or identify if warpage in an electronic system (e.g., or even a semiconductor device) may be due to improper ball contact. Once confirmed, the next steps would be to address the warpage issue with mechanical remedies, such as optimizing the torque of the nuts, which may hold down the heatsink onto the semiconductor package.

The present disclosure may attempt to have contact structures connected in a daisy chain fashion on a semiconductor package and a motherboard and check for collective continuity as suggested below:
Multiplexed pin/s or NCTF (non-critical to function) functionality at the periphery of the package may be re-purposed to have on-Package discrete resistors along with few contact structures on-board in a daisy chain fashion to ensure tight co-planar connection between socket/package and motherboard.
A few unused pins of an MIPI-60 connector may be re-purposed to inject a Test Pattern and verify for the desired pattern based on the contact structure(s) used.
For segments, which may have the luxury of large package real estate, contact structure configurable as resistors might not a major concern. But for smaller packages, it may be needed to synthesize the contact structures as part of a substrate.
This detection method may be extended to detect any warpage at package level where there may be multiple silicon dies or chiplets on an interposer or substrate.

In the context of the present disclosure, the term “coplanar” may refer to components that may lie in the same plane or on the same flat surface. In other words, coplanar components may be configured in such a way that they can be contained within a single plane without any of them protruding or extending out of that plane.

Accordingly, the present disclosure generally relates to an electronic system including a semiconductor package and a circuit board. The semiconductor package and the circuit board may include contact structures configured or configurable to have an output terminal of one contact structure connected to an input terminal of another contact structure so as to render a continuous electrical pathway through the contact structures, and wherein the continuous electrical pathway may render an output pattern in response to an electrical stimulus introduced to the electronic system. The contact structures may be configured in a daisy chain manner forming a series connection.

The present disclosure also generally relates to a method for identifying warpage in an electronic system (e.g., a semiconductor system). The method may include identifying for contact structures (there can be one or more contact structures) in the electronic system, introducing an electrical stimulus to the electronic system, wherein the electronic system may include a semiconductor package and a circuit board, wherein the semiconductor package and the circuit board may include contact structures configured to have an output terminal of one contact structure connected to an input terminal of another contact structure so as to render a continuous electrical pathway through the contact structures, and wherein the continuous electrical pathway may render an output pattern in response to an electrical stimulus introduced to the electronic system. The method may further include identifying for the presence or absence of the output pattern and determining for the presence or absence of warpage in the electronic system from the presence or absence of the output pattern. The contact structures are the main components used in the present method to test for any warpage in the electronic system.

The present disclosure also generally relates to a method for forming an electronic system. The method may include forming a semiconductor package and coupling the semiconductor package to a circuit board. The method may further include arranging contact structures on the semiconductor package and circuit board, wherein the contact structures may be configured to have an output terminal of one contact structure connected to an input terminal of another contact structure so as to render a continuous electrical pathway through the contact structures, and wherein the continuous electrical pathway may render an output pattern in response to an electrical stimulus introduced to the electronic system.

Advantageously, identification of a problematic contact area by injecting known patterns and verifying desired outputs at various positions along the package may help validation engineers as well as customers isolate the problematic area on-board. With the proposed method, there may be no need to send the motherboard back to the factory for a debug and issue fix, which may help drastically reduce downtime of systems in field and laboratory, thereby saving costs of lost billing time if system was down and faster execution during the validation phase.

To more readily understand and put into practical effect the present disclosure, particular aspects will now be described by way of examples and not limitations, and with reference to the drawings. For the sake of brevity, duplicate descriptions of features and properties may be omitted.

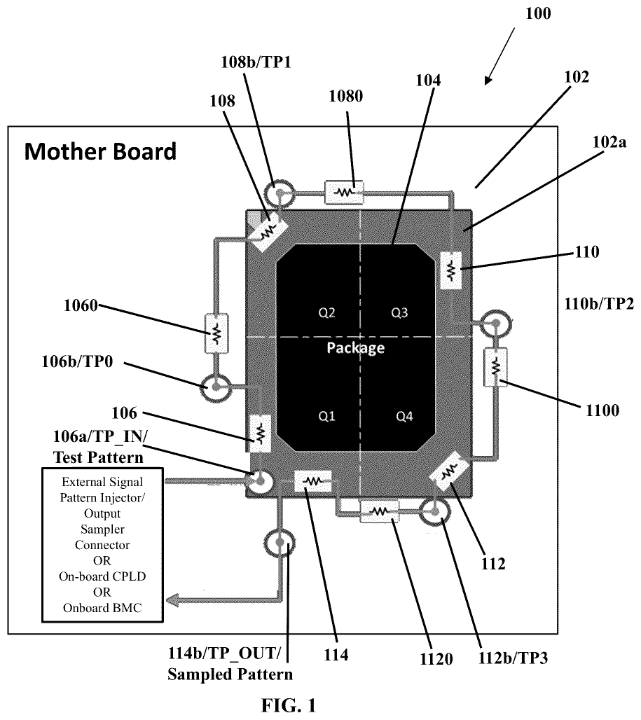

FIG. 1 shows a top view of an electronic system 100 according to an aspect of the present disclosure.

The electronic system 100 may include a main circuit board (e.g., a printed circuit board or a motherboard 102), and a semiconductor package 102a.

In one aspect, the electronic system 100 may be a combination of semiconductor package 102a assembled on a motherboard 102 by a mechanical retainer in a fully assembled mechanical chassis.

The semiconductor package 102a may further include one or more semiconductor dies 104. Additional semiconductor packages may also be provided in the semiconductor package 102a.

In the context of the present disclosure, the term “semiconductor package”, interchangeably referred to as silicon package and an integrated circuit package (IC package), or simply as “package”, may be a protective enclosure or housing that protects a semiconductor component or integrated circuit (IC). It may provide mechanical support, electrical connectivity, and protection against corrosion and environmental factors such as moisture, dust, and mechanical stress. The package may incorporate electrical connections, in the form of metal leads, exposed pads or pins that provide the means to connect the semiconductor package/IC to an external circuit or system. Such connections may allow for the transmission of electrical signals between the semiconductor package/IC and other components. The package may come in various shapes and sizes to accommodate different types of semiconductor package/IC. Non-limiting examples of package may include dual in-line package (DIP), quad flat package (QFP), ball grid array (BGA), land grid array (LGA) and small-outline integrated circuit (SOIC), etc.

The semiconductor package 102a may be coupled to a circuit board (e.g., motherboard 102). The bottom face of the semiconductor package 102a may include input/outputs (I/O) (e.g., land grid arrays (LGAs), pins, pads, balls, etc.) that electrically and mechanically connect with the corresponding I/O of the circuit board.

A plurality of discrete electronic components may be provided in the electronic system 100. In one aspect, the discrete electronic components may be coupled to a circuit board (e.g., motherboard 102). In another aspect, the discrete electronic components may be coupled to the semiconductor package 102a. In yet another aspect, the discrete electronic components may be coupled to the circuit board (e.g., motherboard 102) and the semiconductor package 102a.

In the context of the present disclosure, the term “discrete electronic components” or for brevity, “electronic components”, may refer to individual electronic components that are separate and distinct entities, which can be electrically connected. The “discrete electronic components” are herein interchangeably termed “contact structures”, as the discrete electronic components may not be critical to the function of the electronic system (e.g., or even a semiconductor device of the electronic system), but are structures that can be contacted to form a continuous electrical connection (pathway) for rendering the output pattern. Non-limiting examples of such contact structures may include resistors, capacitors, inductors, diodes, or transistors (such as field-effect transistor (FET), bipolar junction transistor (BJT)). The transistors may be of the N-P-N (negative-positive-negative) type or P-N-P (positive-negative-positive) type and/or may include ferrite beads.

In the aspect shown in FIG. 1, a first contact structure 106, a second contact structure 108, a third contact structure 110, a fourth contact structure 112, and a fifth contact structure 114 may be provided on the semiconductor package 102a.

For the sake of illustration shown in FIG. 1, the first to fifth contact structures 106, 108, 110, 112, 114 may be arranged in a clockwise manner and may surround the semiconductor package 102a. Apart from the first to fifth contact structures 106, 108, 110, 112, 114, further contact structures 1060, 1080, 1100, 1120 may also be configured on the mother board 102. The further contact structures 1060, 1080, 1100, 1120 may also be arranged in a clockwise manner and may surround the semiconductor package 102a. Understandably, the mother board 102 is the main circuit board.

The first contact structure 106 may be coupled to a substrate of the semiconductor package 102a. The substrate may be a circuit board, which may be in turn coupled to a mainboard (e.g., motherboard 102). In certain non-limiting instances, the contact structures are part of the semiconductor package 102a. That is to say, the contact structures may be formed on the semiconductor package 102a (e.g., formed on a substrate of the semiconductor package 102a. Nevertheless, the semiconductor package 102a may be coupled to a circuit board, regardless of whether the circuit board is a main circuit board (such as a mother board) or a subsidiary circuit board (such as a circuit board configured as a substrate that is part of the semiconductor package 102a. The second contact structure 108 may be coupled to the substrate of the semiconductor package 102a. The third contact structure 110 may be coupled to the substrate. The fourth contact structure 112 may be coupled to the substrate. The fifth contact structure 114 may be coupled to the substrate.

The first to fifth contact structures 106, 108, 110, 112, 114 and the further contact structures 1060, 1080, 1100, 1120 may be arranged in a daisy chain manner (connected in series). The first contact structure 106 may be electrically connected to further contact structure 1060, which may in turn be electrically connected to the second contact structure 108, which may in turn be electrically connected to further contact structure 1080, which may then be electrically connected to the third contact structure 110, which may in turn be electrically connected to further contact structure 1100, which may in turn be electrically connected to the fourth contact structure 112, which may in turn be electrically connected to further contact structure 1120, which may then be electrically connected to the fifth contact structure 114.

The daisy-chained contact structures 106, 108, 110, 112, 114 on the semiconductor package 102a and the contact structures 1060, 1080, 1100, 1120 on the main circuit board (e.g., mother board 102) may include test points to probe a waveform when injected with an automated test pattern from an external connector like MIPI-60 or from an on-board Complex Programmable Logic Device (CPLD).

One or more of the contact structures 106, 108, 110, 112, 114, 1060, 1080, 1100, 1120 may include an input terminal and an output terminal. For example, the first contact structure 106 may include an input terminal 106a and an output terminal 106b, the further contact structure may include an input terminal (not shown) electrically connected to output terminal 106b and an output terminal (not shown) that is electrically connected the second contact structure 108, the second contact structure 108 may include an input terminal (not shown) and an output terminal 108b, the further contact structure 1080 may include an input terminal and an output terminal (both terminals not shown), the third contact structure 110 may include an input terminal (not shown) and an output terminal 110b, the further contact structure 1100 may include an input terminal and an output terminal (both terminals not shown), the fourth contact structure 112 may include an input terminal (not shown) and an output terminal 112b, the further contact structure 1120 may include an input terminal and an output terminal (both terminals are not shown), and the fifth contact structure 114 may include an input terminal (not shown) and an output terminal 114b.

For illustration purposes, a couple of test points are shown in circles in the electronic system 100 in FIG. 1 to identify a warpage location (e.g., an area). The test points may coincide with any of the input terminals or any of the output terminals of the contact structures 106, 108, 110, 112, 114, 1060, 1080, 1100, 1120. In one aspect, the input terminal 106a of the first contact structure 106 may be set as an initial test point TP_IN, the output terminal 106b of the first contact structure 106 may be set as a test point TP0, the output terminal 108b of the second contact structure 108b may be set as a test point TP1, the output terminal 110b of the third contact structure 110 may be set as a test point TP2, the output terminal 112b of the fourth contact structure 112 may be set as a test point TP3, and finally the output terminal 114b of the fifth contact structure 114 may be set as a final test point TP_OUT.

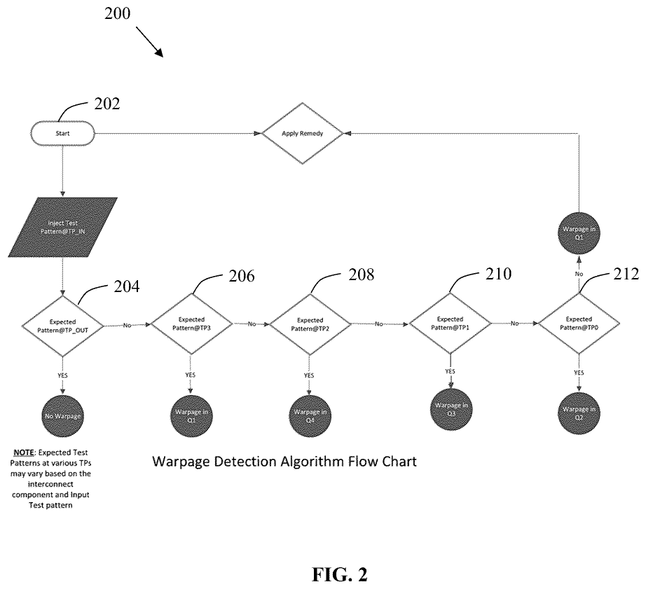

FIG. 2 shows a warpage detection algorithm flow chart 200 applied to the electronic system 100 of FIG. 1. During testing, an electrical stimulus in a form of an electrical waveform/signal/pattern may be introduced or injected to the initial test point TP_IN at the input terminal 106a of the first contact structure. Due to the daisy-chain connection of the contact structures 106, 108, 110, 112, 114, 1060, 1080, 1100, 1120, a continuous electrical pathway may be formed through the respective contact structures. If the mechanical contact of the semiconductor package 102a is uniform across the entire cross-section of the mother board 102 area, then the sampled waveform outputs from each contact structure 106, 108, 110, 112, 114, 1060, 1080, 1100, 1120 may match the expected outputs. The waveform outputs may be expected and predetermined based on the types of discrete contact structures configured in the electronic system 100. On the other hand, whenever there is no output or there may be incorrect pattern/amplitude observed, that may indicate problematic mechanical contact area and possible warpage area. Once the warpage area is identified, there would be multiple mechanical/thermal options to correct the problem quickly.

As illustrated in FIG. 2, at operation 202, the warpage detection testing may be started by injecting an input pattern at test point TP_IN at the input terminal 106a of the first contact structure 106. At operation 204, a final output pattern at test point TP_OUT at the output terminal 114b of the fifth contact structure 114 may be collected. If the final output pattern at test point TP_OUT matches the expected pattern, then it may be concluded that there may be no warpage detected in the electronic system 100.

In the event that the final output pattern at test point TP_OUT does not match the expected output pattern, then the output pattern at test point TP3 (i.e., the output terminal 112b of the fourth contact structure 112) may be examined. In the event that the output pattern at test point TP3 matches the expected output pattern (operation 206), then it may be concluded that a warpage area may be located between test point TP_OUT and test point TP3 (i.e., the area/region Q4 between the fourth and the fifth contact structures 112, 114).

In the event that the output pattern at test point TP3 does not match the expected output pattern, then the output pattern at test point TP2 (i.e., the output terminal 110b of the third contact structure 110) may be examined. In the event that the output pattern at test point TP2 matches the expected output pattern (operation 208), then it may be concluded that a warpage area may be located between test point TP3 and test point TP2 (i.e., the area/region Q3 between the third and the fourth contact structures 110, 112).

In the event that the output pattern at test point TP2 does not match the expected output pattern, then the output pattern at test point TP1 (i.e., the output terminal 108b of the second electronic component 108) may be examined. In the event that the output pattern at test point TP1 matches the expected output pattern (operation 210), then it may be concluded that a warpage area may be located between test point TP2 and test point TP1 (i.e., the area/region Q2 between the second and the third contact structures 108, 110).

In the event that the output pattern at test point TP1 does not match the expected output pattern, then the output pattern at test point TP0 (i.e., the output terminal 106b of the first contact structure 106) may be examined. In the event that the output pattern at test point TP0 matches the expected output pattern (operation 212), then it may be concluded that a warpage area may be located between test point TP1 and test point TP0 (i.e., the area/region Q1 between the first and the second contact structures 106, 108).

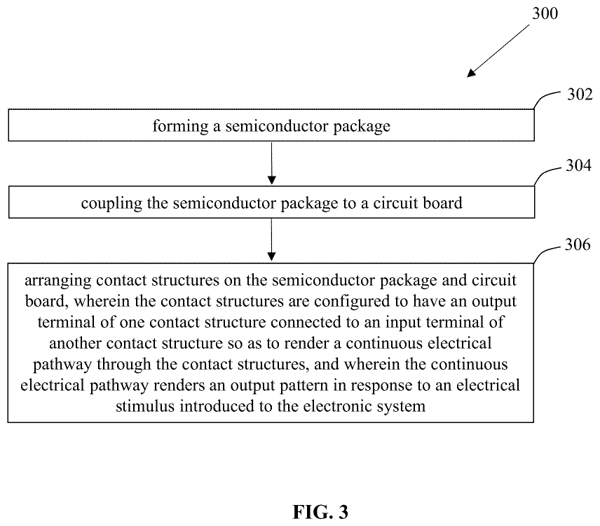

FIG. 3 shows a flow chart illustrating a method for forming an electronic system according to an aspect of the present disclosure.

At operation 302, the method 300 may include forming a semiconductor package.

At operation 304, the method 300 may also include coupling the semiconductor package to a circuit board.

At operation 306, the method 300 may include arranging contact structures on the semiconductor package and circuit board, wherein the contact structures may be configured to have an output terminal of one contact structure connected to an input terminal of another contact structure so as to render a continuous electrical pathway through the contact structures, and wherein the continuous electrical pathway may render an output pattern in response to an electrical stimulus introduced to the electronic system.

### EXAMPLES

Example 1 may include an electronic system having a semiconductor package and a circuit board, wherein the semiconductor package and the circuit board may include contact structures configured or configurable to have an output terminal of one contact structure connected to an input terminal of another contact structure so as to render a continuous electrical pathway through the contact structures, wherein the contact structures may be configured in a daisy chain manner forming a series connection, and wherein the continuous electrical pathway may render an output pattern in response to an electrical stimulus introduced to the electronic system.
Example 2 may include the electronic system of example 1 and/or any other example disclosed herein, wherein the contact structures may be configured on the semiconductor package and on the circuit board, and the contact structures may be positioned between and in contact with both the semiconductor package and the circuit board. In such non-limiting instances, the contact structures may include unused pins of a connector (e.g., MIPI-60 connector) that can be configured to inject a test pattern (i.e., introduce an electrical stimulus).
Example 3 may include electronic system of example 1 and/or any other example disclosed herein, wherein the circuit board may include the contact structures, and some contact structures may be configured proximal to the semiconductor package and some contact structures may be configured distal from the semiconductor package.
Example 4 may include electronic system of example 1 and/or any other example disclosed herein, wherein the contact structures may be formed coplanar to the circuit board.
Example 5 may include the electronic system of example 1 and/or any other example disclosed herein, wherein one or more of the contact structures may include a resistor, a capacitor, an inductor, a diode, or a transistor. The transistor may include a field-effect transistor (FET), bipolar junction transistor (BJT)). The transistors may be of the N-P-N (negative-positive-negative) type or P-N-P (positive-negative-positive) type and/or may include ferrite beads.
Example 6 may include the electronic system of example 1 and/or any other example disclosed herein, wherein the semiconductor package together with the circuit board are configurable as one or more regions for identifying any warpage in the one or more regions, wherein the semiconductor package together with the circuit board are configurable as one region having the contact structures for rendering an overall output pattern to identify any warpage, and if warpage is identified, the semiconductor package together with the circuit board are configurable as two or more regions, each region comprising at least one contact structure for rendering a regional output pattern so as to identify a location of the warpage from the two or more regions.
Example 7 may include the electronic system of example 1 and/or any other example disclosed herein, further including one or more test terminals for introducing the electrical stimulus.
Example 8 may include the electronic system of example 7 and/or any other example disclosed herein, wherein the one or more test terminals may be configured on the semiconductor package and/or on the circuit board.
Example 9 may include a method for identifying warpage in an electronic system. The method may include identifying for contact structures in the electronic system, introducing an electrical stimulus to the electronic system, wherein the electronic system may include a semiconductor package and a circuit board, wherein the semiconductor package and the circuit board may include the contact structures, and the contact structures are configured or configurable to have an output terminal of one contact structure connected to an input terminal of another contact structure so as to render a continuous electrical pathway through the contact structures, and wherein the continuous electrical pathway may render an output pattern in response to an electrical stimulus introduced to the electronic system. The method may further include identifying for the presence or absence of the output pattern and determining for the presence or absence of warpage in the electronic system from the presence or absence of the output pattern.
Example 10 may include the method of example 9 and/or any other example disclosed herein, wherein introducing the electrical stimulus to the electronic system include introducing the electrical stimulus via one test terminal configured on the semiconductor package or on the circuit board; and receiving an output from another test terminal configured on the semiconductor package or on the circuit board, wherein the output may be to be rendered as the output pattern.
Example 11 may include the method of example 9 and/or any other example disclosed herein, wherein introducing the electrical stimulus to the electronic system may include:
(a) providing an electrical input via one test terminal which may be electrically coupled to the semiconductor package; and
(b) transmitting the electrical input through the contact structures to render an output from another test terminal electrically coupled to the semiconductor package, wherein the output may be to be rendered as the output pattern.
Example 12 may include the method of example 11 and/or any other example disclosed herein, wherein transmitting the electrical input through the contact structures may include having the electrical input transmitted through the contact structures which may be configured in a daisy chain manner forming a series connection.
Example 13 may include the method of example 11 and/or any other example disclosed herein, further including repeating steps (a) and (b) for another semiconductor package, if more than one semiconductor package may be configured on the circuit board.
Example 14 may include the method of example 9 and/or any other example disclosed herein, wherein determining for the presence or absence of warpage in the electronic system from the presence or absence of the output pattern may include comparing the output pattern or amplitude of the output pattern, if an output pattern is present, to a pattern rendered from the electronic system with no warpage.
Example 15 may include a method for forming an electronic system. The method may include forming a semiconductor package and coupling the semiconductor package to a circuit board. The method may further include arranging contact structures on the semiconductor package and circuit board, wherein the contact structures may be configured to have an output terminal of one contact structure connected to an input terminal of another contact structure so as to render a continuous electrical pathway through the contact structures, and wherein the continuous electrical pathway may render an output pattern in response to an electrical stimulus introduced to the electronic system.
Example 16 may include the method of example 15 and/or any other example disclosed herein, further including arranging the contact structures in a daisy chain manner forming a series connection.
Example 17 may include the method of example 16 and/or any other example disclosed herein, further including arranging some contact structures proximal to the semiconductor package and arranging some contact structures distal from the semiconductor package.
Example 18 may include the method of example 17 and/or any other example disclosed herein, including forming the contact structures coplanar to the circuit board.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. An electronic system comprising:
a semiconductor package; and
a circuit board,
wherein the semiconductor package and the circuit board comprise contact structures configurable to have an output terminal of one contact structure connected to an input terminal of another contact structure so as to render a continuous electrical pathway through the contact structures, wherein the contact structures are configured in a daisy chain manner forming a series connection, and
wherein the continuous electrical pathway renders an output pattern in response to an electrical stimulus introduced to the electronic system.

2. The electronic system of claim 1, wherein the contact structures are configured on the semiconductor package and on the circuit board, and the contact structures are positioned between and in contact with both the semiconductor package and the circuit board.

3. The electronic system of claim 1, wherein the circuit board comprises the contact structures, and some contact structures are configured proximal to the semiconductor package and some contact structures are configured distal from the semiconductor package.

4. The electronic system of claim 1, wherein the contact structures are formed coplanar to the circuit board.

5. The electronic system of claim 1, wherein one or more of the contact structures are operable as or comprise a resistor, a capacitor, an inductor, a diode, or a transistor.

6. The electronic system of claim 1, wherein the semiconductor package together with the circuit board are configurable as one or more regions for identifying any warpage in the one or more regions, wherein the semiconductor package together with the circuit board are configurable as one region having the contact structures for rendering an overall output pattern to identify any warpage, and if warpage is identified, the semiconductor package together with the circuit board are configurable as two or more regions, each region comprising at least one contact structure for rendering a regional output pattern so as to identify a location of the warpage from the two or more regions.

7. The electronic system of claim 1, further comprising one or more test terminals for introducing the electrical stimulus.

8. The electronic system of claim 7, wherein the one or more test terminals are configured on the semiconductor package and/or on the circuit board.

9. A method for identifying warpage in an electronic system, the method comprising:
identifying contact structures in the electronic system;
introducing an electrical stimulus to the electronic system;
wherein the electronic system comprises:
a semiconductor package; and
a circuit board,
wherein the semiconductor package and the circuit board comprise the contact structures, and the contact structures are configurable to have an output terminal of one contact structure connected to an input terminal of another contact structure so as to render a continuous electrical pathway through the contact structures, and
wherein the continuous electrical pathway renders an output pattern in response to an electrical stimulus introduced to the electronic system;
identifying a presence or absence of the output pattern; and
determining a presence or absence of the warpage in the electronic system based on the presence or absence of the output pattern.

10. The method of claim 9, wherein introducing the electrical stimulus to the electronic system comprises:
introducing the electrical stimulus via one test terminal configured on the semiconductor package or on the circuit board; and
receiving an output from another test terminal configured on the semiconductor package or on the circuit board, wherein the output is to be rendered as the output pattern.

11. The method of claim 9, wherein introducing the electrical stimulus to the electronic system comprises:
providing an electrical input via one test terminal which is electrically coupled to the semiconductor package; and
transmitting the electrical input through the contact structures to render an output from another test terminal electrically coupled to the semiconductor package, wherein the output is to be rendered as the output pattern.

12. The method of claim 11, wherein transmitting the electrical input through the contact structures comprises having the electrical input transmitted through the contact structures which are configured in a daisy chain manner forming a series connection.

13. The method of claim 11, wherein the electronic system comprises an other semiconductor package that is in addition to the semiconductor package, wherein the method further comprises repeating the providing and the transmitting for the other semiconductor package.

14. The method of claim 9, wherein determining the presence or absence of the warpage in the electronic system based on the presence or absence of the output pattern comprises comparing, if an output pattern is present, the output pattern or amplitude of the output pattern to a pattern rendered from the electronic system with no warpage.

15. A method for forming an electronic system, the method comprising:
forming a semiconductor package;
coupling the semiconductor package to a circuit board; and
arranging contact structures on the semiconductor package and circuit board, wherein the contact structures are configured to have an output terminal of one contact structure connected to an input terminal of another contact structure so as to render a continuous electrical pathway through the contact structures, and wherein the continuous electrical pathway renders an output pattern in response to an electrical stimulus introduced to the electronic system.

16. The method of claim 15, further comprising arranging the contact structures in a daisy chain manner forming a series connection.

17. The method of claim 16, further comprising arranging some contact structures proximal to the semiconductor package and arranging some contact structures distal from the semiconductor package.

18. The method of claim 17, comprising forming the contact structures coplanar to the circuit board.
